(19) United States
(12) Patent Application Publication
(10) Pub. No.: US 2007/0070740 A1
(43) Pub. Date: Mar. 29, 2007

(54) Semiconductor memory device having data-compress test mode

(75) Inventor: Seong-Hwi Song, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/528,534

(22) Filed: Sep. 28, 2006

(30) Foreign Application Priority Data
Sep. 28, 2005 (KR) 2005-0090867
May 31, 2006 (KR) 2006-0049121

(51) Int. Cl. G11C 29/00

(52) U.S. Cl. 365/201

(57) ABSTRACT

A semiconductor memory device performs a data-compress test under the same conditions as a normal mode. The semiconductor memory device includes a cell bank for including plural memory cell units for data storage and a data sense amplifying block for sensing and amplifying plural output data of the cell bank and for outputting the data through plural global lines, a compressor, coupled to the data sense amplifying block, for compressing the data transferred through the plural global lines and outputting one-bit compress-data, and data output units for storing the data transferred through the plural of global lines or the compress-data selectively and outputting the data externally.

### FIELD OF THE INVENTION

The present invention relates to a semiconductor memory device; and, more particularly, to a semiconductor memory device for performing a data-compress test mode with high reliability, while embodied in a small size.

### BACKGROUND

As an integration rate of semiconductor memory devices increases rapidly, more than tens of millions of cells are integrated in one memory chip. Therefore, a test for normal or faulty operation is time consuming. Besides accuracy of a test result, an important consideration is how fast the test can be performed. A data-compress test mode is used to a fast test time. In the data-compress test mode, data I/O (hereinafter referred to DQ) pins used in a normal mode are not all used. Data are input into all banks at the same time through some of the DQ pins. Also, data are output from all banks at the same time. By performing a logic operation to a value in a data bus corresponding to each DQ pin, whether the memory chip is normal can be confirmed.

FIG. 1 is a block diagram of a conventional semiconductor memory device performing the data-compress test mode.

Referring to FIG. 1, the conventional semiconductor memory device includes a cell bank 12, a data sense amplifying block 14, a compressor 18 and plural data output units. The cell bank 12 includes plural memory cell units for data storage. The data sense amplifying block 14 senses and amplifies plural outputs of the cell bank 12 and outputs the data through plural test-global lines TGIO_0 to TGIO_15 or global lines GIO_0 to GIO_15 in response to a test signal TM. The compressor 18 compresses the data transferred through the plural test-global lines TGIO_0 to TGIO_15 and outputs one-bit compress-data. The data output units store the data transferred through the global lines GIO_0 to GIO_15 or the compress-data and outputs stored data outside.

The number of the data output units corresponds to the number of the global lines. The data output unit 20 outputs the data transferred through a corresponding global line. Because each data output unit corresponding to each global line is embodied in same circuit, only one global line GIO_0 and the data output unit 20 is described in FIG. 1 The data output unit 20 is provided with a register 22 20 for storing the data transferred through the global line or the compress-data and a data pad 24 for externally outputting data IO from the register 22.

The semiconductor memory device mainly consists of two parts which are a bank area 10 and a peripheral area. The 25 bank area 10 includes blocks for data storage, such as the cell bank 12, the data sense amplifying block 14 and the compressor 18. The peripheral area includes a driving block for the access to the bank area 10, such as the data output unit 20.

FIG. 2 is a schematic circuit diagram of the data sense amplifier 16 shown in FIG. 1.

The data sense amplifying block 14 includes plural data sense amplifiers DBSA0 to DBSA15 in order to sense and amplify corresponding data among the plural output data of the cell bank 12. Because data sense amplifiers DBSA0 to DBSA15 have the same configurations, only the data sense amplifier DBSA0 is described.

As shown, the data sense amplifier 16 includes a sense amplifier 16a and a line selector 16b. The sense amplifier 16a senses and amplifies an input signal IN. The line selector 16b outputs an output signal DT of the sense amplifier 16a selectively through the global line GIO_0 or the test-global line TGIO_0 in response to the test signal TM.

The line selector 16b includes an inverter I1 and logic NAND gates ND1 and ND2. The inverter I1 inverts the test signal TM. The first logic NAND gate ND1 receives the output signal DT of the sense amplifier 16a and an output signal of the inverter I1, outputting into the global line GIO_0. The second logic NAND gate ND2 receives the output signal DT of the sense amplifier 16a and the test signal TM, outputting into the test-global line TGIO_0.

The operation of the data sense amplifier 16 is explained below.

The data sense amplifier 16 senses and amplifies the output signal IN of the cell bank 12, generating an output. When the test signal TM is inactivated in a low level, the line selector 16b outputs the output signal DT of the sense amplifier 16a into the global line GIO_0. In response to activation of the test signal TM, the line selector 16b outputs the output signal DT of the sense amplifier 16a into the test-global line TGIO_0.

The data sense amplifier 16 senses and amplifies the corresponding data of the cell bank 12, outputting into the global line GIO_0 in a normal mode, when the test signal TM is inactivated. In the data-compress mode, the data sense amplifier 16 senses and amplifies the corresponding data and outputs into the test-global line TGIO_0

FIG. 3 is a schematic circuit diagram of the compressor 18 shown in FIG. 1.

Referring to FIG. 3, the compressor 18 is provided with four logic XNOR gates XNOR1 to XNOR4 and a logic AND gate AD1.

The first logic XNOR gate XNOR1 receives data through first to fourth test-global lines TGIO_0 to TGIO_3. The second logic XNOR gate XNOR2 receives data through fifth to eighth test-global lines TGIO_4 to TGIO_7. The third logic XNOR gate XNOR3 receives data through ninth to twelfth test-global lines TGIO_8 to TGIO_11. The fourth logic XNOR gate XNOR3 receives data through thirteenth to sixteenth test-global lines TGIO_12 29 to TGIO_15. The logic NAND gate AD1 receives outputs of four logic XNOR gates XNOR1 to XNOR4, outputting compress-data TGIO_CMP.

When the data transferred through first to sixteenth test global lines TGIO_0 to TGIO_15 have a same logic level, the compressor 18 using the logic XNOR gates XNOR1 to XNOR 4 and the logic AND gate AD1 outputs one-bit compress-data TGIO_CMP as a high logic level H. When at least one of the data transferred through first to sixteenth test global lines TGIO_0 to TGIO_15 has a different level, the one-bit compress-data is output as a low logic level L.

The operation of the semiconductor memory device performing the data-compress test mode is described below, classified into the normal and the data-compress test modes.

At the read driving of the normal mode, the cell bank 12 outputs data corresponding to applied command and address. The data sense amplifying block 14 senses and amplifies the output data of the cell bank 12, transmitting the data to the plural global lines GIO_0 to GIO_15 in response to inactivation of the test signal TM. The registers store the data transmitted through the plural global lines GIO_0 to GIO_15 and output the data externally through the data pads.

The operation in the data-compress test mode is explained below. The cell bank 12 outputs data corresponding to applied command and address. The data sense amplifying block 14 senses and amplifies the output data of the cell bank 12, transmitting the data to the plural test-global lines TGIO_0 to TGIO_15 in response to activation of the test signal TM. The compressor 18 determines the logic level of the compress-date TGIO_CMP and outputs the data, based on whether the data transmitted through the plural test-global lines TGIO_0 to TGIO_15 have the same level. The register 22 stores the compress-data TGIO_CMP and outputs the data externally through the data pad 24.

When the compress-data TGIO_CMP has the logic level H, the result of the data-compress test represents a pass. When the compress-data TGIO_CMP has the logic level L, the result of the data-compress test represents a fail.

The semiconductor memory device performing the data-compress test mode in accordance with the conventional scheme includes the compressor within the bank area. As the integration of the semiconductor memory device is higher, a size of the bank should be smaller and it is difficult for each bank to include the compressor and the data sense amplifier.

The data sense amplifier includes the line selector for selecting the lines in response to the test signal, and the sense amplifier for sensing and amplifying corresponding data. Accordingly, embodying the sense amplifier and the line selector in a limited area is difficult. Embodying the data sense amplifier such a restricted area creates a problem in the reliability of the sense operation.

In addition, the data-compress test does not operate in a normal mode or similar circumstances. The reliability for the test also decreases because lines for data transmission in the normal and the data-compress test modes are different. While the data are transmitted through the global lines in the normal mode, the data are transmitted through the test-global lines in the data-compress test mode.

### SUMMARY OF THE INVENTION

It is, therefore, an object of the present invention to provide a semiconductor memory device, wherein restriction of area is reduced and a data-compress test is performed in a similar manner as normal mode operation.

In accordance with an aspect of the present invention, there is provided a semiconductor memory device, including a cell bank for including plural memory cell units for data storage and a data sense amplifying block for sensing and amplifying plural output data of the cell bank and for outputting the data through plural global lines, a compressor for compressing the data transferred through the plural global lines and outputting one-bit compress-data, and data output units for storing the data transferred through the plural of global lines or the compress-data selectively and outputting the data externally.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram of a conventional semiconductor memory device performing a data-compress test mode;

FIG. 2 is a schematic circuit diagram of a data sense amplifier shown in FIG. 1;

FIG. 3 is a schematic circuit diagram of a compressor shown in FIG. 1;

FIG. 4 is a block diagram of the semiconductor memory device performing the data-compress test mode in accordance with the present invention;

FIG. 5 is a schematic circuit diagram of a data sense amplifier shown in FIG. 4;

FIG. 6 is a schematic circuit diagram of a compressor shown in FIG. 4; and

FIG. 7 is a schematic circuit diagram of a storage unit shown in FIG. 4.

### DETAILED DESCRIPTION OF THE INVENTION

Hereinafter, a semiconductor memory device in accordance with the present invention will be described in detail referring to the accompanying drawings.

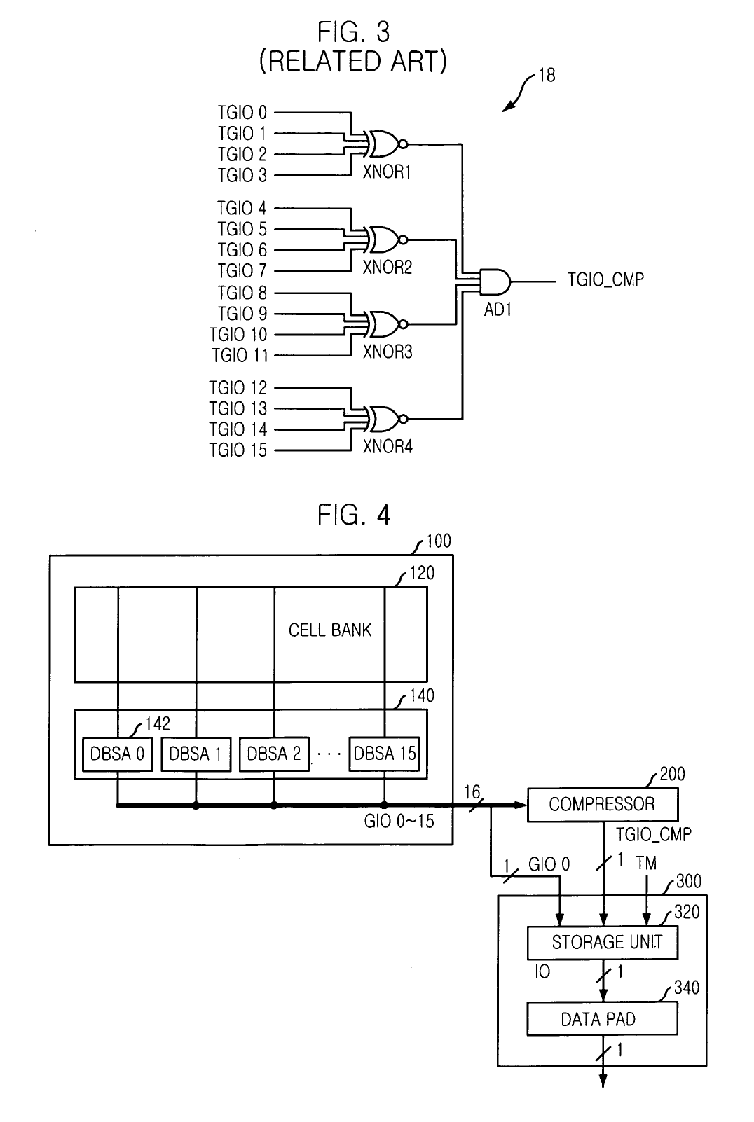

FIG. 4 is a block diagram of the semiconductor memory device performing the data-compress test mode in accordance with the present invention.

Referring to FIG. 4, the semiconductor memory device performing the data-compress test mode in accordance with the present invention includes a cell bank 120, a data sense amplifying block 140, a compressor 200 and data output units. The cell bank 120 includes plural memory cell units for data storage. The data sense amplifying block 140 senses and amplifies plural output data of the cell bank 120, outputting the data through plural global lines GIO_0 to GIO_15. The compressor 200 compresses the data transferred through the plural global lines GIO_0 to GIO_15 and outputs one-bit compress-data TGIO_CMP. And the data output units selectively store the data transferred through the global lines or the compress-data TGIO_CMP in response to a test signal TM and output the data outside.

The number of the data output units corresponds to the number of the global lines. Each data output unit outputs the data transferred through a corresponding global line. A data output unit for outputting the data transferred through the global line GIO_0 is described in an accompanying drawing.

The data output unit 300 includes a storage unit 320 for selectively storing the data transferred through the global line GIO_0 or the compress-data TGIO_CMP in response to the test signal TM and a data pad 340 for outputting output data IO of the storage unit 320 externally.

The other data output units for outputting the data transferred through the other global lines GIO_1 to GIO_15 include registers for storage of an input data and data pads without reference to the test signal TM.

However, the data output unit which selectively outputs the data transferred through the global line or the compress-data is not restricted to the data output connected to the global line GIO_0, but can be anyone of the data output units.

The cell bank 120 and the data sense amplifying block 140 are formed in bank area 100. The compressor 200 and the data output unit 300 are formed in the peripheral area.

As shown, the semiconductor memory device in accordance with the present invention transmits the data through the same global lines GIO_0 to GIO_15 without reference to the normal or the data-compress mode. Accordingly, the data-compress test is performed in the same manner as the normal mode. As a result, the reliability of the data-compress test increases.

Because the same global lines GIO_0 to GIO_15 are used in the normal and data-compress test modes, the area is reduced by removing the plural test-global lines TGIO_0 to TGIO_15, which is conventionally used to transfer the data from the data sense amplifying block 14 to the compressor 18 in the data-compress mode.

Because the same global lines GIO_0 to GIO_15 are selectively used regardless of the operation mode, in the data sense amplifying block 140 of the present invention, the line selection according to the operation modes is unnecessary. Accordingly, the block for selecting the global lines GIO_0 to GIO_15 or the test-global lines TGIO_0 to TGIO_15 according to the modes is removed in the data sense amplifying block 140 of the present invention. Finally, a relatively extended bank area is secured by forming the compressor 200 in the peripheral area.

A circuit embodiment of each block is described below in detail referring to the accompanying drawings.

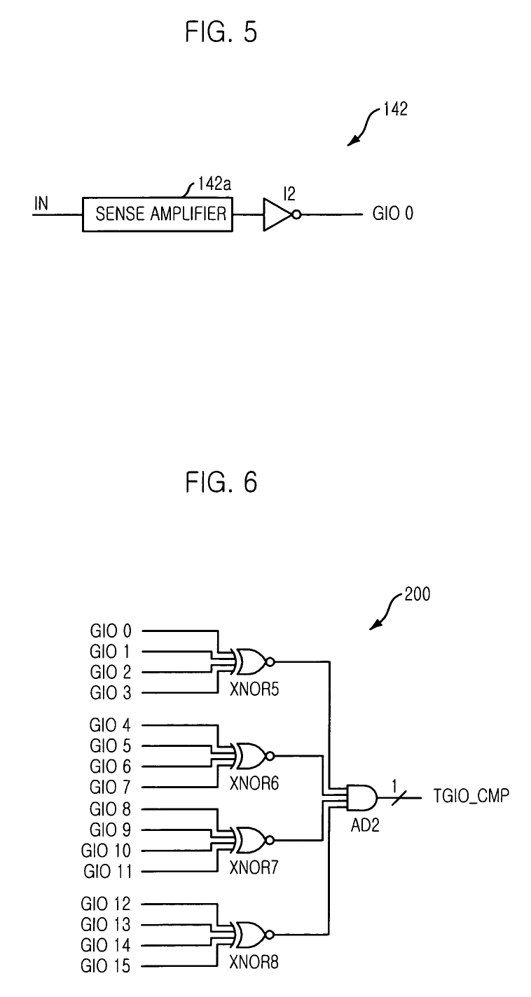

FIG. 5 is a schematic circuit diagram of the data sense amplifier 142 shown in FIG. 4.

The data sense amplifying block 140 includes plural data sense amplifier DBSA0 to DBSA15 in order to sense and amplify corresponding data among the plural output data of the cell bank 120. Because the data sense amplifiers DBSA0 to DBSA15 are embodied similarly, only the data sense amplifier 142 is described.

As shown, the data sense amplifier 142 includes a sense amplifier 142a and an inverter I2. The sense amplifier 142a senses and amplifies an input signal IN. The first inverter I2 inverts an output of the sense amplifier 142a and outputs the data to the global line GIO_0.

Observing the operation briefly, the sense amplifier 142a senses and amplifies a logic level of the input signal IN.

The first inverter I2 inverts the output of the sense amplifier 142a, outputting the data to the global line GIO_0. The first inverter I2 is a device for driving the output of the sense amplifier 142a.

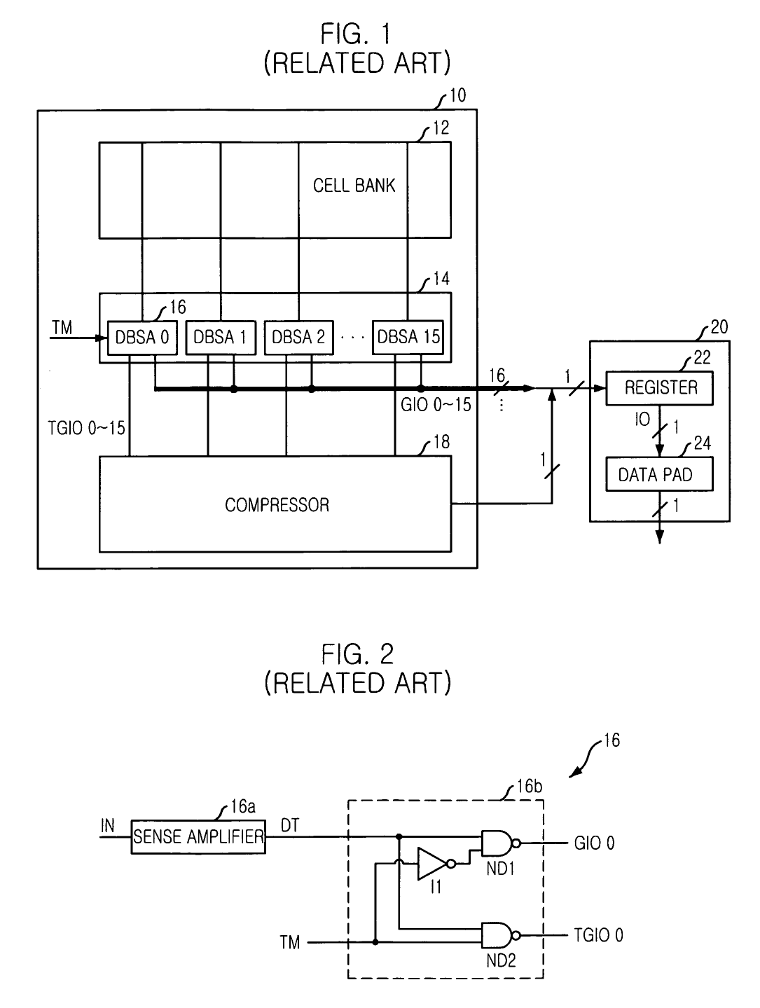

As explained above, the data sense amplifier 142 of the present invention includes no line selector, as compared with the conventional scheme in FIG. 2. The data sense amplifier 142 according to the present invention can be embodied within a restricted area.

Because drivability and reliability of the sense amplifier are in proportion to an area, in which the sense amplifier is embodied, the sense amplifier embodied in wider area provided by the present invention has improved drivability and reliability.

FIG. 6 is a schematic circuit diagram of a compressor 200 shown in FIG. 4.

The compressor 200 includes four logic XNOR gates XNOR5 to XNOR8 and a logic AND gate AD2. The first logic XNOR gate XNOR5 receives data through first to fourth global lines GIO_0 to GIO_3. The second logic XNOR gate XNOR6 receives data through fifth to eighth global lines GIO_4 to GIO_7. The third logic XNOR gate XNOR7 receives data through ninth to twelfth global lines GIO_8 to GIO_11. The fourth logic XNOR gate XNOR8 receives data through thirteenth to sixteenth global lines GIO_12 to GIO_15. The logic NAND gate AD2 receives outputs of four logic XNOR gates XNOR5 to XNOR8, outputting a compress-data TGIO_CMP.

Comparing the compressor 200 with the conventional compressor 18 shown in FIG. 3, it is different that data are input through the plural global lines GIO_0 to GIO_15 in spite of the same circuit configuration.

Because the data are transmitted in the data-compress test mode through the global lines used to transmit the data in the normal mode, all the tests are performed under the same conditions as the normal mode. The reliability for the tests is improved.

Observing the operation briefly, when the data transmitted through the plural global lines GIO_0 to GIO_15 have the same logic level, the compressor 300 outputs compress-data TGIO_CMP as a high logic level H. When at least one of the data transferred through the plural global lines GIO_0 to GIO_15 has a different level, the compress-data is output as a low logic level L.

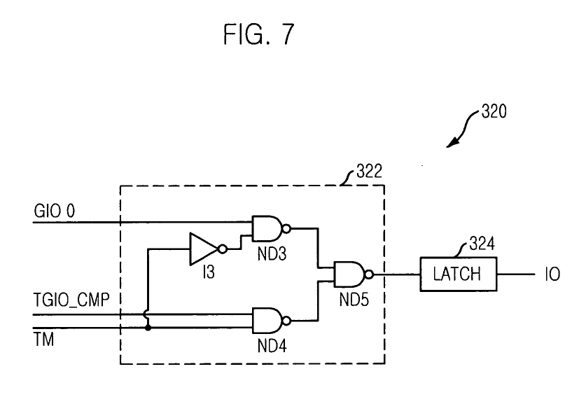

FIG. 7 is a schematic circuit diagram of a storage unit 320 shown in FIG. 4.

The storage unit 320 includes an input unit 322 and latch 324. The input unit 322 receives the data transferred through the global line GIO_0 or the compress-data TGIO CMP in response to the test signal TM. The latch 324 stores the output of the input unit 322.

The input unit 322 is provided with an inverter I3 and three logic NAND gates ND3 to ND5. The second inverter I3 inverts the test signal TM. The first logic NAND gate ND3 receives the data transferred through the global line GIO_0 and an output of the inverter I3. The second logic NAND gate ND4 receives the compress-data TGIO_CMP and the test signal TM. The third logic NAND gate ND5 receives outputs of the first and the second logic NAND gates ND3 and ND4.

The operation of the storage unit 320 is briefly described below. When the test signal TM is inactivated as a logic level L, the input unit 322 receives the data transferred through the global line GIO_0. When the test signal TM is activated as a logic level H, the input unit 322 receives the compress-data TGIO_CMP. Continuously, the latch 324 stores the output of the input unit 322.

When the test signal TM is inactivated, i.e., in the normal mode, the storage unit 320 stores the data transferred through the global line GIO_0. In the data-compress test mode, the storage unit 320 stores the compress-data TGIO_CMP.

The operation of the semiconductor memory device performing data-compress test mode in FIG. 4 is described below, which is classified into the normal mode and the data-compress test mode.

At the read driving of the normal mode, the cell bank 120 outputs data corresponding to input command and address. The data sense amplifying block 140 senses and amplifies the output data of the cell bank 120 and transmits the data through the corresponding global lines GIO_0 to GIO_15. In response to inactivation of the test signal TM, the storage units store the data transmitted through the corresponding global lines GIO_0 to GIO_15 and output the data externally through the data pads.

Continuously, the operation in the data-compress test mode is explained hereinafter. The cell bank 120 outputs data corresponding to applied command and address. The data sense amplifying block 140 senses and amplifies the plural output data of the cell bank 120 and transmits the data through the plural global lines GIO_0 to GIO_15. The compressor 200 determines the logic level of the compress-date TGIO_CMP and outputs the data, which depends on whether the data transmitted through the plural global lines GIO_0 to GIO_15 have the same level. In response to activation of the test signal TM, the storage units 320 stores the compress-data TGIO_CMP and outputs the data outside through the data pad 340.

When the compress-data TGIO_CMP has the logic level H, the result of data-compress test represents a pass. When the compress-data TGIO_CMP has the logic level L, the result of data-compress test represents a fail.

As described above, the semiconductor memory device in accordance with the present invention transmits the data through the same global lines GIO_0 to GIO_15 without reference to the normal or the data-compress mode. Accordingly, the reliability of the test increases. Because the data are transmitted in the data-compress test mode through the global lines used in the normal mode, all of the tests are performed under the same conditions.

Because the conventional plural test-global lines TGIO_0 to TGIO_15 are removed and the compressor 200 is formed in the peripheral area, the area of restriction is reduced at the bank area. By using the global lines GIO_0 to GIO_15 commonly without reference to the modes, the plural test-global lines TGIO_0 to TGIO_15 conventionally used to transmit the data from the data sense amplifying block 14 to the compressor 18 in the data-compress mode is removed.

The operation speed and the reliability of the data sense amplifying block 140 in accordance with the present invention are improved as compared with the conventional data sense amplifying block 14. The area restriction for the data sense amplifier is reduced by removing the line selector in the data sense amplifier. Because the operation speed and the reliability of the data sense amplifier increase in proportion to an increase in occupied area, the speed and the reliability for sensing and amplifying data in the data sense amplifier of the present invention are improved.

The efficiency of layout increases by common use of the global lines GIO regardless of the normal and the data-compress test modes. Because the data-compress test is performed under the same conditions as normal operation through the common lines, the reliability of data-compress test increases.

The present application contains subject matter related to Korean patent applications Nos. 2005-0090867 and 2006-0049121, respectively, filed in the Korean Patent Office on Sep. 28, 2005 and May 31, 2006, the entire contents of which are incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. A semiconductor memory device for performing a data-compress test mode, comprising:
a cell bank for including plural memory cells for data storage, and a data sense amplifying block for sensing and amplifying plural output data of the cell bank and for outputting the data through plural global lines;
a compressor, coupled to the data sense amplifying block, for compressing data transmitted through the plural global lines and outputting one-bit compress-data; and
a data output block for selecting the data transmitted through the plural global lines or the compress-data in response to a test signal and outputting the data.

2. The semiconductor memory device as recited in claim 1, wherein the compressor compares logical levels of the plural input data and outputs the one-bit compress-data according to the result.

3. The semiconductor memory device as recited in claim 1, wherein the compressor performs a logic XNOR operation to the data transmitted through the plural global lines and outputs the one-bit compress-data.

4. The semiconductor memory device as recited in claim 1, wherein the cell bank and the data sense amplifying block are formed in the cell bank area, and the compressor and the data output block are formed in an area outside the cell bank area.

5. The semiconductor memory device as recited in claim 1, wherein the data sense amplifying block includes the plural data sense amplifier for sensing and amplifying corresponding data among the plural output data of the cell bank.

6. The semiconductor memory device as recited in claim 5, wherein the data sense amplifier includes:
a sense amplifier for sensing and amplifying input data; and
a inverter for inverting output data of the sense amplifier and outputting the data to the global line.

7. The semiconductor memory device as recited in claim 1, wherein the data output block includes the same number of data output units as the bit number of the data output from the bank, and the compress-data is input to one of the plural data output units.

8. The semiconductor memory device as recited in claim 7, wherein the data output unit includes:
a storage unit for storing the data transmitted through corresponding global line among the plural global lines; and
a data pad for outputting output data of the storage units.

9. The semiconductor memory device as recited in claim 7, wherein the data output unit receiving the compress data includes:
a storage unit for selectively storing the data transmitted through corresponding global line among the plural global lines or the compress-data in response to the test signal; and
a data pad for outputting output data of the storage units.

10. The semiconductor memory device as recited in claim 9, wherein the storage unit includes:
an input unit for selecting and receiving the data transmitted through the global line or the compress-data in response to the test signal; and
a latch for storing and outputting output data of the input unit.

11. The semiconductor memory device as recited in claim 10, wherein the input unit includes:
a second inverter for inverting the test signal;
a first logic NAND gate for receiving the data transmitted through the global line and an output of the second inverter;
a second logic NAND gate for receiving the compress-data and the test signal; and
a third logic NAND gate for receiving outputs of the first and the second logic NAND gates.

12. A method of performing a data-compress test mode, comprising:
outputting data stored in a cell corresponding to applied command and address;
sensing and amplifying the data and outputting the data through plural global lines;
outputting one-bit compress-data having different logic levels, which depends on whether the data transmitted through the plural global lines have the same logic level; and
selecting and outputting the compress-data or the data transferred through the global line according to modes such as the data-compress test mode and the normal mode.
